(19) United States
(12) Patent Application Publication
(10) Pub. No.: US 2011/0130292 A1
(43) Pub. Date: Jun. 2, 2011

(54) ROOM-TEMPERATURE SUPERCONDUCTOR, PERFECT CONDUCTOR, PROTONIC CONDUCTOR, FERROMAGNETIC BODY, ELECTROMAGNETIC COIL, AND METHOD FOR PRODUCING THESE MATERIALS

(76) Inventor: Yasushi Kawashima, Tokyo (JP)

(21) Appl. No.: 13/055,275

(22) PCT Filed: Jun. 18, 2009
(86) PCT No.: PCT/JP2009/061123

§ 371 Date: Jan. 21, 2011

(30) Foreign Application Priority Data
Jul. 25, 2008 (JP) 2008-192707

(51) Int. Cl. H01L 39/00; H01L 39/24; H01F 5/00; H01B 12/00; H01B 5/00; H01B 1/04; H01F 1/01; B82Y 30/00

(52) U.S. Cl. 505/150; 505/300; 335/299; 174/125.1; 174/126.2; 252/502; 252/62.56; 29/599; 977/734; 423/448

(57) ABSTRACT

There is provided a room-temperature superconductor that has a very simple structure and enters a state of superconductivity at room temperature. Also, there is provided a method for making the room-temperature superconductor. Further, there is provided a protonic conductor having superconductivity at room temperature. The room-temperature superconductor comprises a substance composed of graphene and a proton donor.

### TECHNICAL FIELD

The present invention relates to a room-temperature superconductor, a perfect conductor, a protonic conductor, a ferromagnetic body, an electromagnetic coil, and a method for making them.

### BACKGROUND ART

Superconductor and perfect conductor technology is expected to offer promising applications including magnetic levitation of linear motor trains, transmission lines and other wires for power supply, wiring materials for semiconductor devices, energy storage coils, and Josephson devices.

Studies have been made to date based on highly complex and expensive oxide composed principally of rare metal such as lanthanoid yttrium, bismuth, and tellurium. However, these materials in general have to be cooled down to so-called ultra-low temperature in order of −100 degrees Celsius or lower, or at least down to −70 degrees C. in order for superconductivity phenomenon to occur. In this context, room-temperature superconductors and perfect conductors have long been pursued that can enter the state of superconductivity at room temperature without the need of coolant for maintaining the superconducting state (see Patent Literature PTL 1).

### Citations List

### Patent Literature

PTL 1: Japanese Patent Application Laid-Open Publication No. H01-290532

### Non-Patent Literature

NPL 1: Thomas E. Weller, Mark Ellerby, Siddharth S. Saxena, Robert P. Smith, and Neal T. Skipper, “Superconductivity in the intercalated graphite compounds C6Yb and C6Ca,” Nature Physics, vol. 1, pp. 39-41, 2005.

### SUMMARY OF THE INVENTION

### Technical Problem

Graphite is known to become superconducting at a low temperature in order of 2 K. It is also known that its superconducting transition temperature (Tc) is raised when calcium is provided between its graphite layers. In that case, however, the raised superconducting transition temperature (Tc) will still be as low as 11.5 K, which is far lower than the superconducting transition temperatures of the above-mentioned oxide superconductors (see PTL 1).

Also, a protonic conductor can be used in applications including fuel cells and electrochemical devices such as an electrochemical capacitor and a chemical pump in fuel gas generation systems for fusion reactors. Nonetheless, the state of the art has not hitherto been able to offer a protonic conductor that exhibits room-temperature superconductivity, which, if available, should be of infinite significance.

In view of the above-identified problems found in the state of the art, an object of the present invention is to provide a room-temperature superconductor that has very simple structure and yet exhibits room temperature superconductivity; to provide a method for making the room-temperature superconductor; and to provide a protonic conductor that exhibits room-temperature superconductivity.

### Solution to Problem

The inventor of the present invention had been examined the characteristics of graphite (black lead) and found that some reaction does occur between the graphite and alkane that are believed to be chemically highly stable, which lead to the conception of the present invention.

Specifically, in order to solve the above-identified problem, the room-temperature superconductor according to a first aspect of the present invention is a room-temperature superconductor that comprises (a) a substance composed of graphene and (b) a proton donor.

Also, the room-temperature superconductor of the present invention according to a second aspect of the present invention is, in the room-temperature superconductor of the first aspect, characterised in that the substance composed of graphene is at least one selected from the group consisting of carbon nanotube, fullerene, and graphite.

Further, the room-temperature superconductor according to a third aspect of the present invention is, in the room-temperature superconductor of the second aspect, characterised in that the graphite is carbon fiber.

Also, the room-temperature superconductor according to a fourth aspect of the present invention is, in the room-temperature superconductor of any one of the first to third aspects, characterised in that the proton donor is hydrocarbon.

Further, the room-temperature superconductor according to a fifth aspect of the present invention is, in the room-temperature superconductor according to the fourth aspect, characterised in that the hydrocarbon is straight-chain hydrocarbon.

According to a sixth aspect of the present invention, there is provided a method for making a room-temperature superconductor, comprising bringing a proton donor into contact with a substance composed of graphene.

According to a seventh aspect of the present invention, there is provided a perfect conductor comprising (a) a substance composed of graphene and (b) a proton donor.

According to an eighth aspect of the present invention, there is provided a method for making a perfect conductor, comprising bringing a proton donor into contact with a substance composed of graphene.

According to a ninth aspect of the present invention, there is provided a protonic conductor comprising (a) a substance composed of graphene and (b) a proton donor.

According to a tenth aspect of the present invention, there is provided a method for making a protonic conductor, comprising bringing a proton donor into contact with a substance composed of graphene.

According to an eleventh aspect of the present invention, there is provided a ferromagnetic body comprising (a) a substance composed of graphene and (b) a proton donor.

According to a twelfth aspect of the present invention, there is provided a method for making a ferromagnetic body, comprising bringing a proton donor into contact with a substance composed of graphene.

According to a thirteenth aspect of the present invention, there is provided an electromagnetic coil, comprising one selected from the group consisting of the room-temperature superconductor of any one of the first to fifth aspects and the perfect conductor of the seventh aspect.

### Advantageous Effects of the Invention

The room-temperature superconductor, the perfect conductor, and the protonic conductor according to the present invention offer long-awaited landmark solution for humanity in that they make it possible to realize the effects of superconductivity that can be stably maintained at room temperature, zero-resistivity characteristics, and proton conductivity by only requiring highly simple, readily available, and inexpensive substances, i.e., (a) the substance composed of graphene and (b) the proton donor.

The ferromagnetic body according to the present invention is a lightweight ferromagnetic body comprising these readily available and inexpensive substances, i.e., the substance composed of graphene and the proton donor.

The method for making the room-temperature superconductor according to the present invention makes it possible to obtain the room-temperature superconductor by just bringing these very simple and inexpensive substances, i.e., the substance composed of graphene and the proton donor, into contact with each other.

The method for making a perfect conductor according to the present invention makes it possible to obtain the perfect conductor by just bringing these very simple and inexpensive substances, i.e., the substance composed of graphene and the proton donor, into contact with each other.

The method for making a protonic conductor according to the present invention makes it possible to obtain the protonic conductor by just bringing these very simple and inexpensive substances, i.e., the substance composed of graphene and the proton donor, into contact with each other.

The method for making a ferromagnetic body according to the present invention makes it possible to obtain the room-temperature superconductor by just bringing these very simple and inexpensive substances, i.e., the substance composed of graphene and the proton donor, into contact with each other.

The electromagnetic coil according to the present invention comprises the room-temperature superconductor or the perfect conductor, and it is a room temperature superconducting coil with reduced running costs by virtue of its manufacturability, inexpensiveness, and no-need-of-cooling characteristics.

### BRIEF DESCRIPTION OF THE DRAWINGS

In the drawings:

FIG. 1 is a schematic illustration of regular collective circulating motion of π electron pairs in a graphene structure of graphite;

FIG. 2 is a schematic representation of a state where a proton and a hydrogen anion are supplied to the π electron pairs in the collective circulating motion illustrated in FIG. 1;

FIG. 3 is a schematic representation of a magnetization and measurement system of the present invention for application of magnetic field and measurement of magnetic flux density;

FIG. 4 is a graph depicting change over time in magnetic field following stoppage of application of the magnetic field, the change being observed by the magnetization and measurement system of FIG. 3 in the absence of a sample;

FIG. 5 is a graph depicting resulting change over time in magnetic flux density after stoppage of application of magnetic field in a case where a substance composed of graphenes in use is graphite;

FIG. 6 is a graph corresponding to that of FIG. 5 with the vertical axis being a logarithmic axis;

FIG. 7A is a top view schematically illustrating a ring-shaped container 11 used in verification as perfect conductor;

FIG. 7B is a top view schematically illustrating a holding jig 12 used in the verification as the perfect conductor;

FIG. 7C is a cross-sectional view of the holding jig 12;

FIG. 8A is a top view schematically illustrating the magnetization and measurement system.

FIG. 8B is a front view of the magnetization and measurement system.

FIG. 9A depicts change in the magnetic field detected when the ring-shaped container was removed from the magnetization and measurement system;

FIG. 9B depicts change in the magnetic field when the ring-shaped container that had been disconnected and had been again placed in the magnetization and measurement system was removed from the magnetization and measurement system;

FIG. 10 depicts results of verification, where a sample comprising graphite and n-octane was magnetized, stored at room temperature, and magnetic field distributions along an axial direction were checked 24 days and 50 days, respectively, after the magnetization of the sample;

FIG. 11A depicts data confirming the presence of the magnetic field due to a ring current in a case where graphite is used as the substance composed of graphenes and the magnetic field is maintained at room temperature;

FIG. 11B depicts data confirming the presence of the magnetic field due to the ring current in a case where carbon fiber is used as the substance composed of graphenes and the magnetic field is maintained at room temperature;

FIG. 11C depicts data confirming the presence of the magnetic field due to the ring current in a case where a single-wall nanotube is used as the substance composed of graphenes and the magnetic field is maintained at room temperature;

FIG. 11D depicts data confirming the presence of the magnetic field due to the ring current in a case where C60 fullerene is used as the substance composed of graphenes and the magnetic field is maintained at room temperature;

FIG. 12 depicts data confirming the presence of the magnetic field due to the ring current, the magnetic field being maintained at room temperature, where n-hexane, 2,2,4-trimethylpentane, 1-octene, and n-pentadecane are used as the proton donor in lieu of the n-octane as shown in portions (a) to (d), respectively;

FIG. 13A is a front view (cross-sectional view) schematically illustrating a Meissner effect verification apparatus 30;

FIG. 13B is a top view (cross-sectional view) of the same apparatus;

FIG. 13C is a cross sectional view of a glass container 20;

FIG. 13D is a schematic representation of a shape of the graphite that was used;

FIG. 14 depicts changes in the magnetic field in response to different applied magnetic fields, portions (a) to (e) corresponding to the applied magnetic fields of 180 G, 150 G, 100 G, 50 G, and 10 G, respectively;

FIG. 15 depicts changes in the magnetic field in response to different applied magnetic fields, portions (a) to (c) corresponding to the applied magnetic fields of 1 G, 0.1 G, and a level less than 0.1 G and yet larger than 0 G, respectively; and

FIG. 16 depicts ferromagnetism with respect to a superconductor comprising graphite and n-octane where a magnetic field equal to or larger than 10 G is applied, portions (a) to (d) corresponding to the applied magnetic fields of 150 G, 100 G, 50 G, and 10 G, respectively.

### REFERENCE NUMERALS

1 Coil
2 Sample
3 Container
4a Jig
4b Jig
5 Hall probe
11 Ring-shaped container
11a Body portion
11b Connecting portion
12 Holding jig
13 Magnetization and measurement system
13b Fixing jig
13c Hall probe holder
13d Hall probe
13e X-Z direction positioning stage
13f Cylindrical body
13g Arm portion
13h Screw
13i Screw
13j Round bar
13k Induction coil
13l Magnetization and measurement unit
20 Glass container
21 Lid
22 Proton donor
23 Syringe
23a Plunger
30 Meissner effect verification apparatus
31 Placement jig
32 Coil
33 Hall probe
34a Magnetic shield container
34b Magnetic shield container

### DESCRIPTION OF THE EXEMPLARY EMBODIMENTS

Graphite composed of graphenes, according to conventional assumption, is believed to be chemically inert and non-polar. In addition, since hydrocarbon is also chemically inert, no interaction is expected to occur between the graphite and the hydrocarbon on the premise of such commonly-accepted knowledge even when they are brought into contact with each other.

However, in fact, a superconductivity phenomenon was observed at room temperature as the graphite and the hydrocarbon were brought into contact with each other.

This phenomenon could be described as follows.

In a graphene structure of graphite, π electrons are considered to be delocalized and move freely through the entire graphene layer.

However, it can be assumed that the graphene structure in fact partly possess ionic character. The following depicts how localization of the electron could occur resulting in such ionic character.

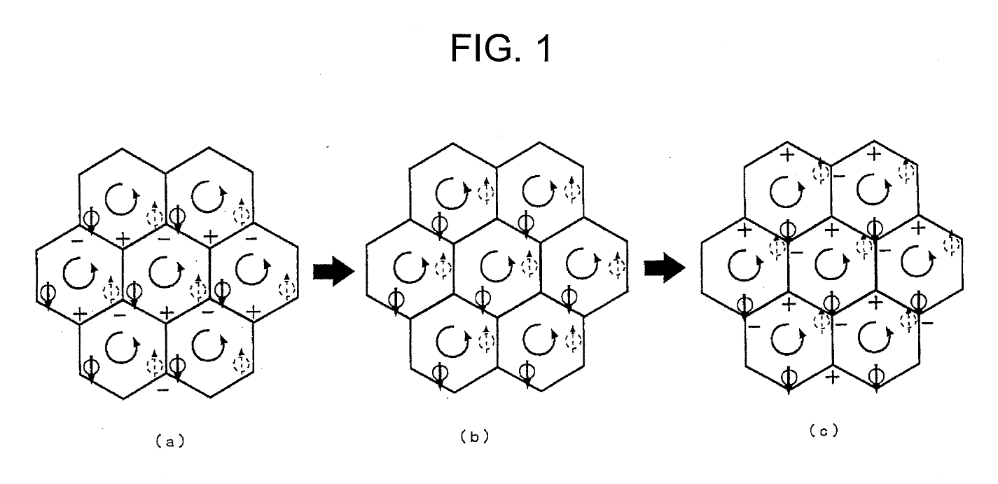

In the graphene structure of graphite, the it electrons do not move completely freely, but all of the π electron pairs circulate at the same speed in each of hexagonal rings, as shown in the states (a) to (c) of FIG. 1.

By virtue of this regular collective circulating motion of the π electron pairs, all of the carbon atoms become a cation and an anion alternately at high speed, so that acid-base site pairs appear intermittently through the entire graphite surface.

These π electrons are capable of entering π orbital lobes on upper and lower sides of the graphite surface, and accordingly two π electrons at an atom site pass each other, one of the two it electrons moving in the upper side of the π lobe and the other moving in the lower side of the π lobe so that mutual repulsion is as small as possible, with the two orbitals separated by carbon cation in-between.

In the (a) to (c) states of FIG. 1, a solid-line circle schematically represents the π electron on the upper side of the graphene surface, and the dotted-line circle schematically represents the π electron on the lower side of the graphene surface. An arrow in FIG. 1 schematically represents the direction of spin of each π electron.

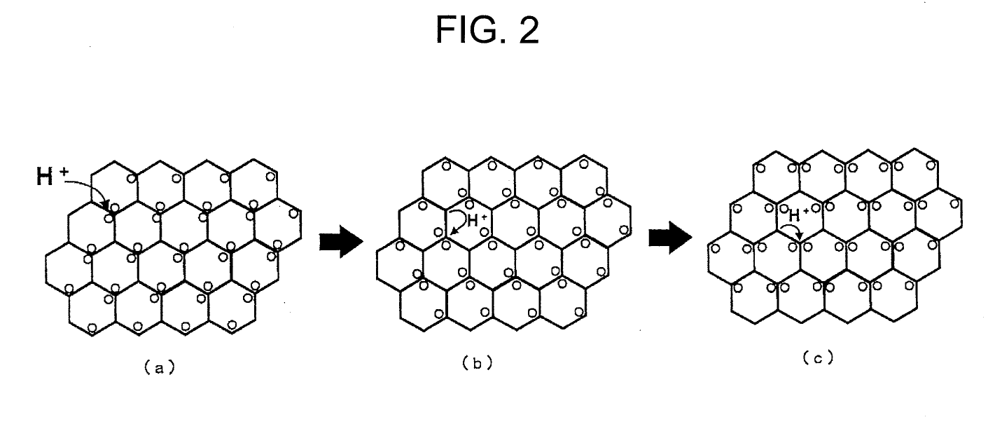

When a proton donor (saturated hydrocarbon, i.e., alkane, is contemplated here) is brought into contact with the graphene structure, two hydrogen atoms are abstracted from a hydrocarbon molecule of the alkane to result in alkene, and a hydrogen anion originating from one of these two hydrogen atoms is allowed to bind to the carbon cation in the graphite. However, at the atom site where two electrons pass each other at high speed, the one of the electrons is found on the side of the other surface, and a proton attracted by the carbon that became anion is not allowed to combine with the carbon concentrating the electron pair between the proton and the carbon atom. This means that the carbon atom that became anion attracts the proton, but immediately becomes cation and repels the proton, as a result of which the proton moves. See the states (a) to (c) of FIG. 2, where a round mark represents the π electron, and H⁺ represents the proton.

In other words, the proton enters a state where it can move freely on the graphene surface without activation energy, and, by virtue of this proton, the room temperature superconductivity phenomenon should occur.

The graphene in the context of the present invention may be a monolayer film, a laminated graphene, a graphite (black lead), fullerene, and carbon nanotube, which may be a single-layer type (single-walled carbon nanotube) or multi-layer type (multi-walled carbon nanotube).

Carbon fiber is preferable in that its shape as such facilitate production of electromagnetic coils (superconducting coils). More preferably, the carbon fiber may be so-called graphitic fiber (having tensile elastic modulus equal to or larger than 340 Gpa), which has high degree of graphitization allowing exploitation of particularly high magnetic flux density.

Advantageously, these substances composed of graphenes, with very small specific gravity in order of 2 to 2.2, are very inexpensive compared with special alloys conventionally for use in high-temperature superconductors.

Meanwhile, the proton donor may be a substance that can provide the proton, for example, hydrocarbon. Preferably, the hydrocarbon may be saturated hydrocarbon, and, in particular, straight-chain saturated hydrocarbon, which readily releases pairs of hydrogen atoms allowing exploitation of higher effects.

Further, the proton donor in use may preferably be in a liquid state and generally in a state of liquid at room temperature. For example, when a straight-chain saturated hydrocarbon is to be used, the carbon number preferably falls within the range from 5 to 16. Practically, the carbon number should be in the range from 6 to 15. Nevertheless, when the proton donor is used at temperatures other than the room temperature, straight-chain saturated hydrocarbon in use may have a carbon number that does not necessarily falls within the above range. For example, at a low temperature, the one having smaller carbon number may be used. At a high temperature (i.e., a temperature higher than the room temperature), the one that has a larger carbon number may be used. Also, when the straight-chain saturated hydrocarbon is to be used, it does not need to be a pure one but may be mixture of straight-chain saturated hydrocarbons having different carbon numbers.

When making the room-temperature superconductor of the present invention, it is in principle only necessary to bring the proton donor into contact with the substance composed of graphenes. For example, such simple techniques may be employed as applying a liquid proton donor in drops onto the substance composed of graphenes, or soaking the substance composed of graphenes in the proton donor.

When a proton donor having low boiling point is to be used, the proton donor is likely to be lost by evaporation, and, in this case, superconductive property, perfect conductor property, and proton conductive property may be lost. Accordingly, it is preferable that the proton donor be contained in a closed container and/or an additional system be provided that is configured to supply the proton donor continuously or intermittently, using a pump or other devices that employs effect of gravity, with the amount of decrease in the proton donor kept under monitoring.

Superconducting coils can be readily made using the room-temperature superconductor of the present invention.

Specifically, carbon fiber is wound so as to have a shape of a ring, or alternatively, powdered carbon nanotube, fullerene, or graphite is put into a ring-shaped container. Further alternatively, these powdered substances are mixed with substance that can be readily carbonized such as pitch and tar and formed into a predetermined shape, and then the processed mixture is thermally treated under an inert atmosphere and is carbonized (as a result of this treatment, its part consisting of the readily-carbonized substance will become porous), and made into a shape of a ring (or a coil). The proton donor is brought into contact with either one of the foregoing items. In this manner, the room temperature superconducting coil is obtained.

### EXAMPLES

The following provides more specific description of the examples of the room-temperature superconductor according to the present invention.

### Foundational Verification

### —Methodology of Experimentation

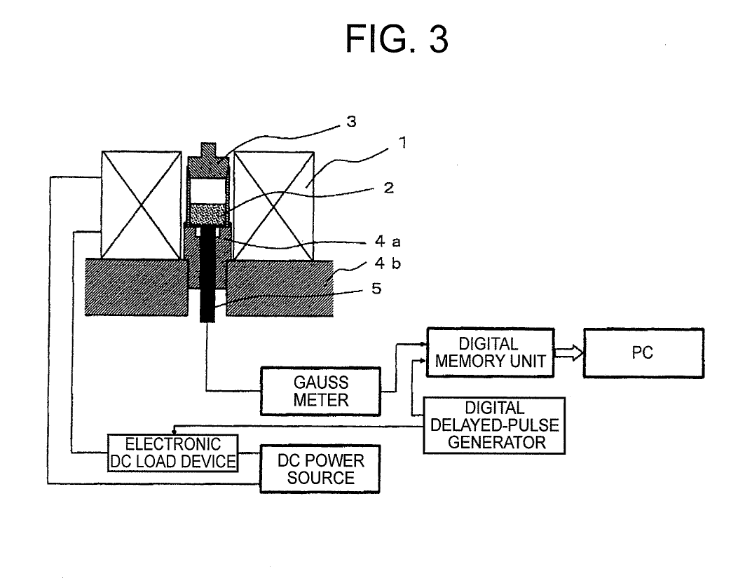

Evaluation was carried out using the device, whose cross section is schematically illustrated in FIG. 3.

Jigs 4a, 4b made of polyvinyl chloride are arranged such that a sample 2 is disposed at the centre of a doughnut-shaped copper foil air core coil 1. The copper foil air core coil 1 has an internal diameter of 22 mm, an outer diameter of 89 mm, a height of 38 mm, inductance of 2.2 mH, and resistance of 0.21 ohm. As a magnetic sensor, a hall probe 5 is disposed at the centre of the jig 4b such that the hall probe 5 is in contact with a bottom portion of a container 3 that contains the sample 2. The container 3 is a weighing bottle with an outer diameter of 18 mm, a height of 26 mm, and an amount of content of approximately 3 mL. The container 3 has a lid.

The hall probe 5 is an axial probe (with a resolution of 0.1 mG) connected to a gaussmeter (F. W. Bell, 7010). Change over time in magnetic force measurements measured by the hall probe 5 is temporarily stored in a digital memory unit and then analyzed by a computer.

A direct-current power source is connected to the copper foil air core coil 1 via an electronic DC load device to control turning on and off of the coil. When the coil is turned on, a magnetic field occurs with magnetic flux density of 400 G (1 G=10⁻⁴ T).

A digital delayed-pulse generator (Stanford Research Systems, Inc., DG535) is connected to the electronic DC load device for driving the electronic DC load device to control turning on and off of the copper foil air core coil (to turn the coil off ten seconds after it was turned on), and transmit a switch-off signal for copper foil air core coil to the digital memory unit such that the digital memory can start recording the change over time in the magnetic force measurements simultaneously with the stoppage of application of the magnetic field by the copper foil air core coil.

All the measurements were made at a room temperature (22 to 24 degrees C.).

Further, in view of the influences of geomagnetism, magnetic force measurements were obtained in the absence of the sample prior to application of respective magnetic field. The measurements were stored to serve as reference values taking the influences of geomagnetism into consideration. The reference value is subtracted from measured data in analysis by the computer so as to remove geomagnetic influences from the measured data.

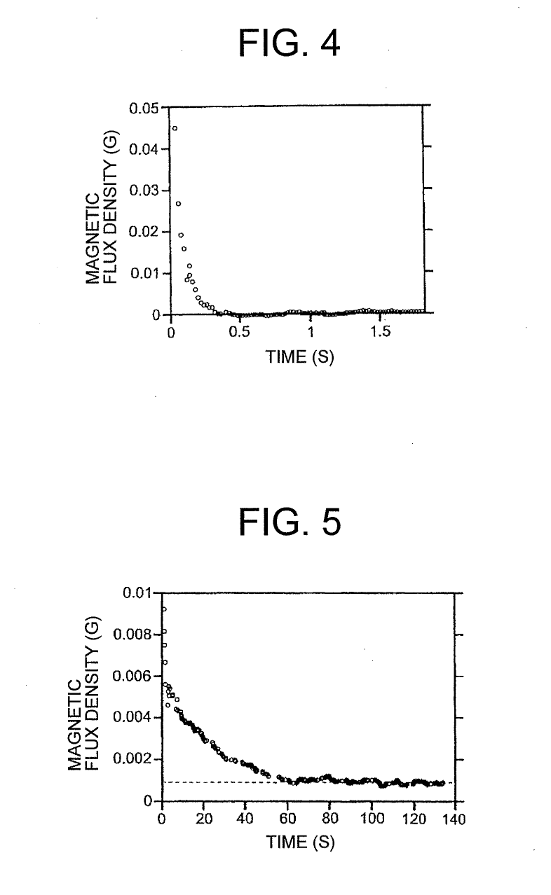

Referring to FIG. 4, there is shown the change over time in the magnetic field after stoppage of application of the magnetic field in the absence of the sample (i.e., a blank case), the change over time being obtained using the device illustrated in FIG. 3.

As indicated by FIG. 4, in the absence of the sample, the observed magnetic flux density was at the zero level at 0.3 second after the stoppage of application of the magnetic field.

### —Results in the Case of Graphite (HOPG)

The substance composed of graphenes used in the experiment is highly-oriented pyrolytic graphite (HOPG; GE Advanced Ceramics, ZYA grade). Twenty pieces of graphite flakes (each having a thickness of 0.05 to 0.4 mm and a mean area of 60 mm²) were put into the weighing bottle and soaked in 400 μL of n-hexane. After the lid was attached to the weighing bottle, magnetic field was applied at the center of the copper foil air core coil 1.

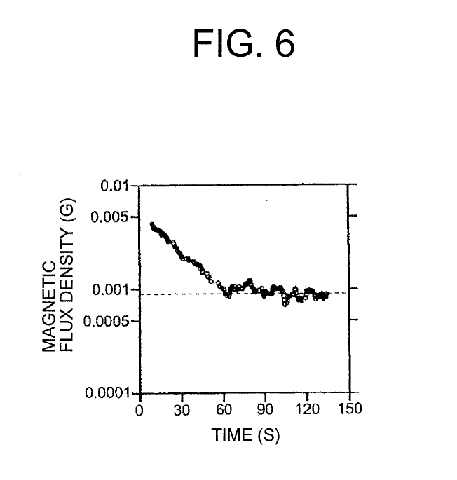

The change in the magnetic flux density after the stoppage of application of the magnetic field is shown in FIG. 5. FIG. 6 is a graph depicting the same change in the magnetic flux density as shown in FIG. 5, with the vertical axis (representing the magnetic flux density) of FIG. 5 indicated by logarithm.

As indicated in FIG. 5, the magnetic flux density gradually decreases for approximately 60 seconds after the stoppage of application of the magnetic field, but thereafter it remains substantially constant at 0.0009 G. Also, when only the graphite is employed (i.e., the graphite is not in contact with the n-hexane), the result is substantially the same as in the blank case, and the magnetic flux density decreased to be at the zero level within 0.8 second.

In a simple resistor-inductor circuit (RL circuit), change in electric current under temporary disturbance is believed to decrease according to the equation: i(t)=i(0)exp(−t/τ), where τ is time constant given by L/R, L being self-inductance of the coil and R being resistance of the coil.

Given the above equation, linear relationship has to exist between the magnetic field and the time if plotting is made with single logarithm as shown in FIG. 6. However, as shown in FIG. 6, nonlinear relationship exists in this example.

The fact of this nonlinearity and the constantly maintained magnetic field indicate that this example exhibits superconducting characteristics and endorses the above-described hypothesis of proton conductivity.

Further, the decrease in the magnetic flux density over 60 seconds after stoppage of application of magnetic field is considered to indicate excessive magnetic field that could not be shielded by the proton current.

### Verification as Perfect Conductor

In order to verify that the continuous magnetic field obtained using a graphite flake sample is due to the electric current, examination was carried out to form an electromagnetic ring that comprises a perfect conductor.

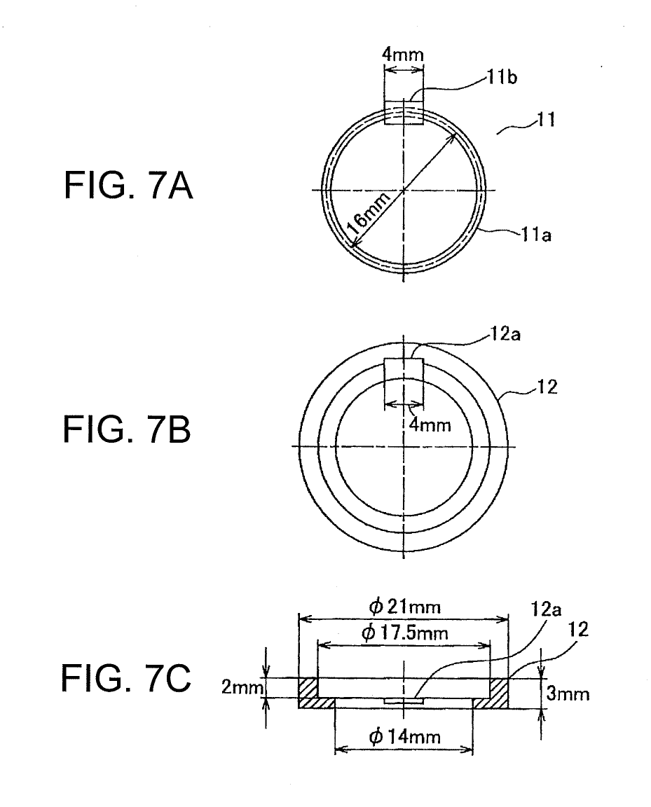

FIG. 7 depicts a ring-shaped container 11 and a holding jig 12 adapted to hold the ring-shaped container 11, which were used in the experiment.

A body portion 11a of the ring-shaped container 11 whose side view is illustrated in FIG. 7A is a polytetrafluoroethylene (which may hereafter be referred to as “PTFE”) tube with an internal diameter of 0.96 mm and an outer diameter of 1.56 mm. The connecting portion 11b is a glass tube with an internal diameter of 1.6 mm, an outer diameter of 2.5 mm, and a length of 4 mm. In order to maintain the ring-shaped container 11 in a substantially true circle shape, the ring-shaped container 11 was connected to the holding jig 12 (made of polytetrafluoroethylene) that includes a notch 12a in its portion corresponding to the connecting portion 11b.

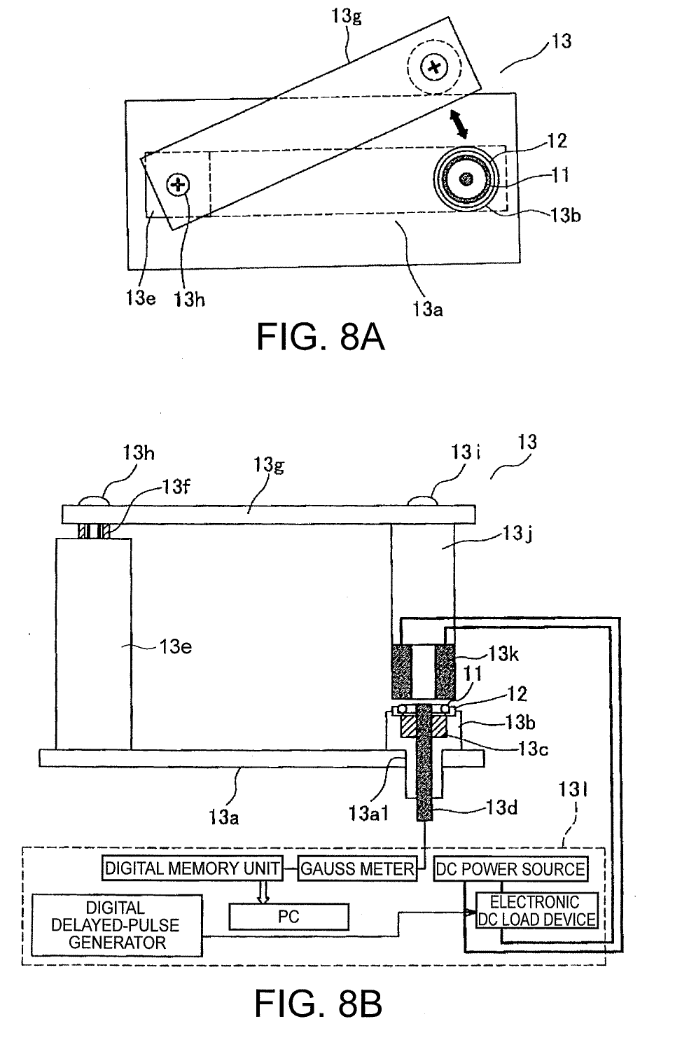

FIG. 8 illustrates a magnetization and measurement system 13. FIG. 8A is a top view illustrating an arm portion 13g rotated to be out of a magnetization position. FIG. 8B is a front view illustrating the arm portion 13g placed in the magnetization position.

A fixing jig 13b made of acrylic resin is fitted with a fixing hole 13a1 provided near one end of the acrylic resin base 13a. A recess is provided on top of the fixing jig 13b such that a hall probe holder 13c made of PTFE is received in the recess such that the ring-shaped container 11 placed in the holding jig 12 is put therein. The fixing jig 13b and the hall probe holder 13c each include a vertically extending throughhole such that the hall probe 13d is received in this throughhole concentrically with the ring-shaped container 11. A diameter of the throughhole of the hall probe holder 13c is substantially the same as the outer diameter of the hall probe 13d, so that the hall probe 13d as such can be slid and moved in a vertical direction and held at that position. In this state, a sensor portion of the hall probe 13d is moved up and down in conjunction with the hall probe 13d in the vertical direction with respect to the ring-shaped container 11, so that it is possible to check a magnetic distribution in the vertical direction of the sample contained in the ring-shaped container 11.

Meanwhile, an X-Z direction positioning stage 13e upstands on the acrylic resin base 13a near the other end thereof. The X-Z direction positioning stage 13e has a shape of a quadrangular prism and is made of aluminum. The plate-shaped arm portion 13g made of acrylic resin is provided at a top end of the X-Z direction positioning stage 13e via the plastic screw 13h and a cylindrical body 13f made of PTFE. Also, the arm portion 13g is held by a plastic screw 13h rotatably thereabout, the plastic screw 13h being an axis of rotation. Further, the arm portion 13g is parallel to the base 13a.

An induction coil 13k (number of turns being 50) is held by a round bar 13j made of acrylic resin and a plastic screw 13i such that the induction coil 13k resides immediately above the ring-shaped container 11 and concentrically with the ring-shaped container 11 when the arm portion 13g is rotated and placed in the magnetization position (indicated by dashed lines in FIG. 8A). This induction coil 13k is adapted to produce induction ring current for the sample within the ring-shaped container 11 so that the magnetic field is generated in the axial direction of the induction coil 13k.

The induction coil 13k and the hall probe 13d are connected to a magnetization and measurement unit 13l.

A direct-current power source is connected via the electronic DC load device to the induction coil 13k, the DC power source being disposed in the magnetization and measurement unit 13l. A digital delayed pulse generator is connected to the electronic DC load device. The digital delayed pulse generator is controlled by the electronic DC load device so that an electric current of about 7 A flows in the induction coil 13k to set the magnetic field detected by the hall probe to 50 G, so that the sample contained in the ring-shaped container 11 is magnetized.

If an energizing period of the induction coil 13k is approximately 15 seconds, a signal is transmitted by the digital delayed pulse generator to the electronic DC load device to stop energization of the coil rapidly.

After that, in order to avoid inconvenience that may undermining the accuracy of measurement, such as Joule heat that is produced in the induction coil 13k and transferred to the sensor close to the head of the hall probe 13d, the arm portion 13g is immediately rotated after stoppage of energization and thus the induction coil 13k is detached from the hall probe 13d.

Meanwhile, the hall probe 13d is connected to a gaussmeter provided in the magnetization and measurement unit 13l (Lake Shore Cryotronics, Inc. Gauss meter: 455; Hall probe: HMNA1904VR). The magnetic force due to the sample contained within the ring-shaped container 11 is detected by the hall probe 13d and the gaussmeter and stored in the digital memory unit.

The data stored in the digital memory unit is loaded into the computer to undergo data analysis as required.

The ring-shaped container 11 is first taken out of a state of connection via the connecting portion 11b, and the substance composed of graphenes is put into the ring-shaped container 11, the substance composed of graphenes being powdered or processed into short fibers as required so that it can be accommodated in the ring-shaped container 11. Following this, the substance composed of graphenes is soaked in a liquid proton donor for one day. After that, the ring-shaped container 11 was placed in a state of connection via the connecting portion 11b, so that the substance composed of graphenes takes a shape of a circular ring. Subsequently, it was checked using a microscope whether or not the substances composed of graphenes are connected to each other within the ring-shaped container 11 so as to be used in the tests as will be hereinafter described in detail.

A highly-oriented pyrolytic graphite (HOPG) is used as the substance composed of graphenes, and n-octane is used as the proton donor, and 0.0344 g of the graphite (HOPG) and 0.0148 g of the n-octane were contained in the ring-shaped container 11.

Also, when storing the sample contained in the ring-shaped container 11, the sample on an as-is-basis is was contained in a closed container that contains the same kind of the proton donor as was used, and stored at room temperature. When the magnetic force is to be measured again after having been stored at room temperature, the sample was taken out of the closed container, and the proton donor attached on the outside of the ring-shaped container 11 was removed therefrom. The ring-shaped container 11 was connected to the holding jig 12, and was in that state connected to the acrylic resin fixing jig 13b of the magnetization and measurement system 13. Thus, the magnetic force was measured using the sensor close to the head of the hall probe 13d and the gaussmeter.

The graphite (HOPG) was used as the substance composed of graphenes and the n-octane used as the proton donor, and the ring-shaped container filled with the sample comprising this graphite and this n-octane was connected to the magnetization and measurement system to carry out magnetization.

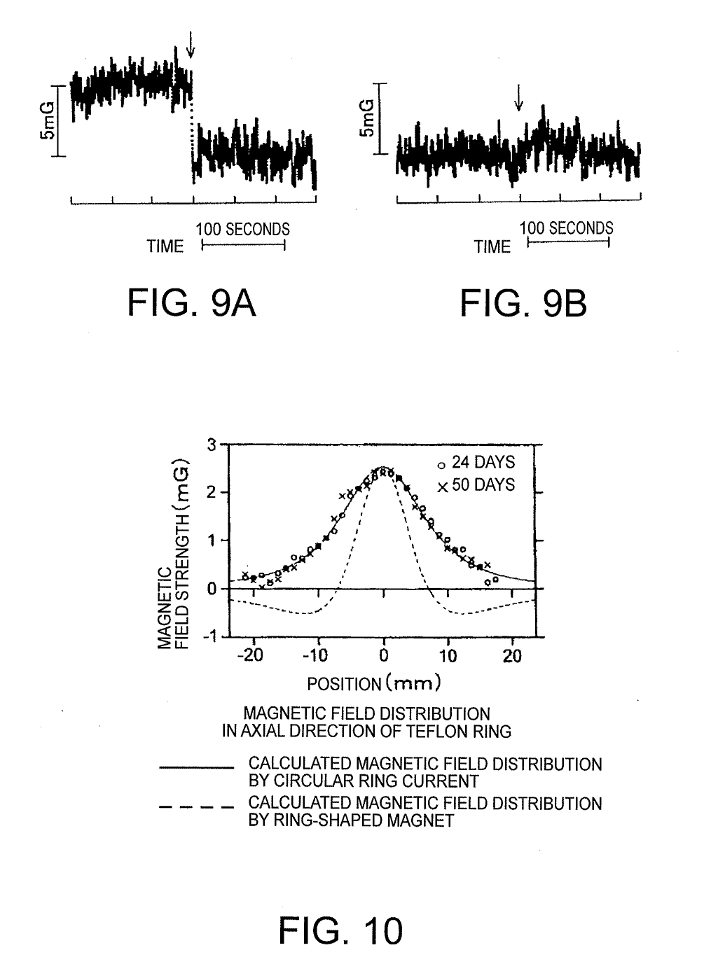

Even after lapse of one hour after the magnetization, the hall probe and the gaussmeter continued to detect the magnetic field as late as one hour after the magnetization. The ring-shaped container filled with the sample was then disconnected from the magnetization and measurement system. FIG. 9A depicts the change in the magnetic field that was detected in that case. At the timing indicated by the arrow in the figure, the ring-shaped container was promptly removed from the system.

It is appreciated from FIG. 9A that the magnetic field that had been continuously detected was produced by the sample comprising the graphite and the n-octane.

Following this, the connection by the connecting portion of this ring-shaped container is temporarily disabled and then enabled again, and the ring-shaped container was placed in the magnetization and measurement system. The change over time in the magnetic field in this case is shown in FIG. 9B. The ring-shaped container was removed from the system at the timing indicated by the arrow in the figure.

It is appreciated from FIG. 9B that the sample that had been separated lost the magnetic field, from which one can confirm that the above-described magnetic field was produced by the rotational current in the electromagnetic coil.

This sample comprising the graphite and the n-octane was again subjected to magnetization, and after the magnetization it was stored at room temperature. Its magnetic field distribution was examined twenty-four days later and 50 days later, respectively, whose results are depicted in FIG. 10.

The magnetic field distribution after 50-day storage agrees with the magnetic field distribution after 24-day storage (this distribution also agrees with the magnetic field distribution immediately after the magnetization), and it is appreciated that the ring current produced by this sample comprising the graphite and the n-octane did not diminish but was continuously maintained, which means that this sample is a perfect conductor.

In the figures, the solid line represents a calculated value of the magnetic field distribution in the central axial direction due to ring current, which is obtained by the following equation Eqn. 1, and the dashed line represents a calculated value of the magnetic field distribution due to ring-shaped magnet. Since the actual magnetic field distribution faithfully agrees with the calculated distribution of the ring current, it was verified that the actual magnetic field was due to the ring current.

In the equation Eqn. 1, H_{z} is the magnetic field strength in the axial direction of the circular ring, a is the radius of the circular ring, and z is the circular ring central axis coordinate.

$${H}_{z} = \frac{1}{2 a} \frac{1}{{( 1 + \frac{{z}^{2}}{{a}^{2}} )}^{\frac{3}{2}}} \qquad ( Eqn 1 )$$

### Example where Other Graphene is Used

In a similar manner to the above-described example, but in place of the graphite (HOPG), the ring-shaped container was filled with a carbon fiber (Nippon Graphite Fiber; YS-95A-60S with tensile elastic modulus of 892 Gpa (catalog value)), single-wall nanotube (Unidym; ultrahigh purity HiPco single-walled carbon nanotube), and C60 fullerene (MTR Ltd., C 60 99.9 5%), respectively. The n-octane was introduced into the ring-shaped container, and the magnetic field was measured in the axial direction for one hour and seven (7) days after the magnetization, respectively.

Since sizing agent is provided on the surface of commercially available carbon fibers, in order to eliminate the effect of it, the carbon fiber in this experiment was soaked in acetone for one month prior to the experiment to remove the sizing agent therefrom.

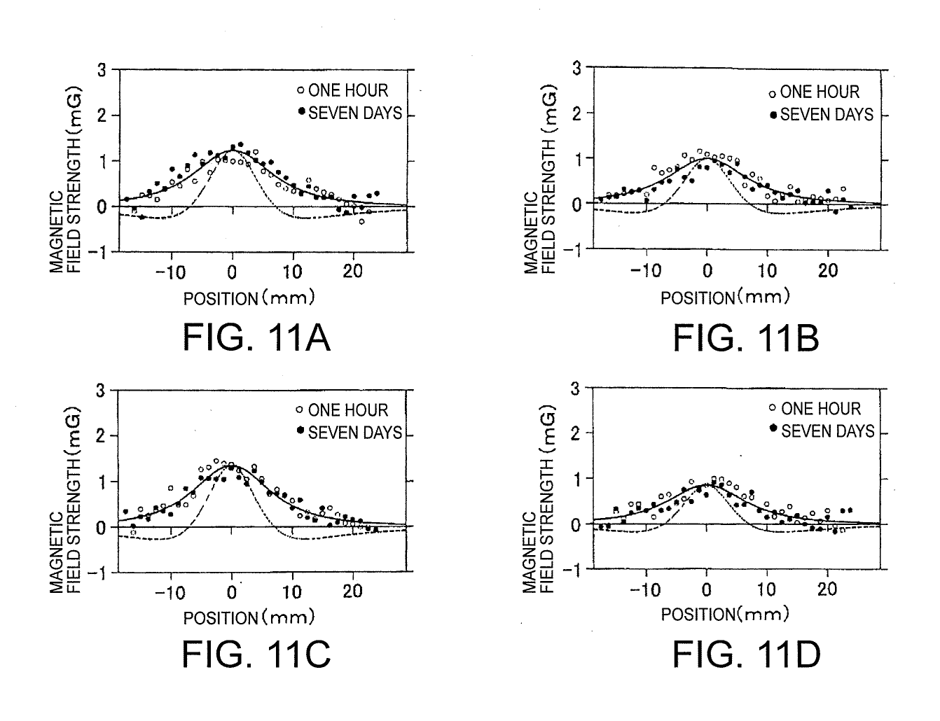

The results are shown in FIGS. 11B, 11C, and 11D along with the results when the graphite (HOPG) was used (i.e., FIG. 11A).

From these figurers, it is appreciated that among these substances composed of graphenes, even when the carbon fiber is used that is relatively inexpensive mass-produced material, it is possible to construct a perfect conductor in the same manner as in the cases of the other substances composed of graphenes. Also, the magnetic field when the fullerene was used is slightly lower than those of the other substances composed of graphenes.

### Examples where Other Proton Donor is Used

The above-described examples used the n-octane as the proton donor. In place of the n-octane, examinations were carried out using n-hexane, 2,2,4-trimethylpentane, 1-octene, and n-pentadecane, respectively.

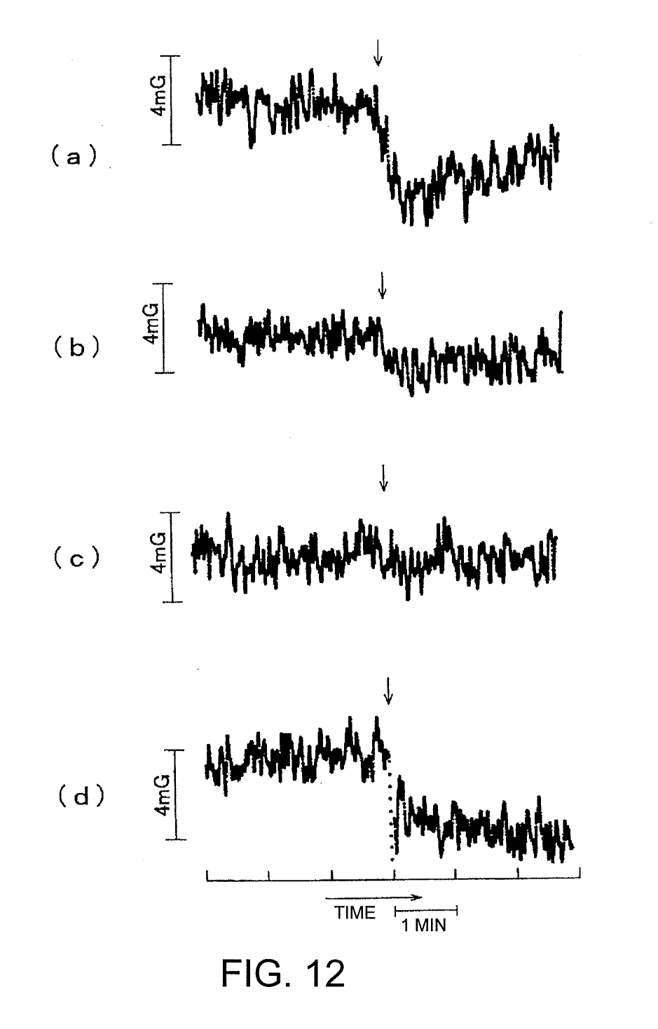

These proton donors were introduced in the ring-shaped container filled with the graphite (HOPG) and connected to the magnetization and measurement system, and the ring current was exited by the magnetization by the same magnetic force. Following this, while the magnetic field was being measured, the ring-shaped container was removed from the magnetization and measurement system. Portions (a) to (d) in FIG. 12 depict the changes in the magnetic field in those cases, respectively (the arrow in the figure represents the timing of the removal of the ring-shaped container).

Judging from the figure, higher magnetic field is available when a straight-chain saturated hydrocarbon such as the n-hexane and the n-pentadecane is used as the proton donor, and, in particular in the case of the hydrocarbon having branched structure or unsaturated bond, a low magnetic field results compared with the case where the straight-chain saturated hydrocarbon is used.

### Verification of Meissner Effect

Examination was carried out to ascertain the presence of the Meissner effect that is characteristic of superconductors.

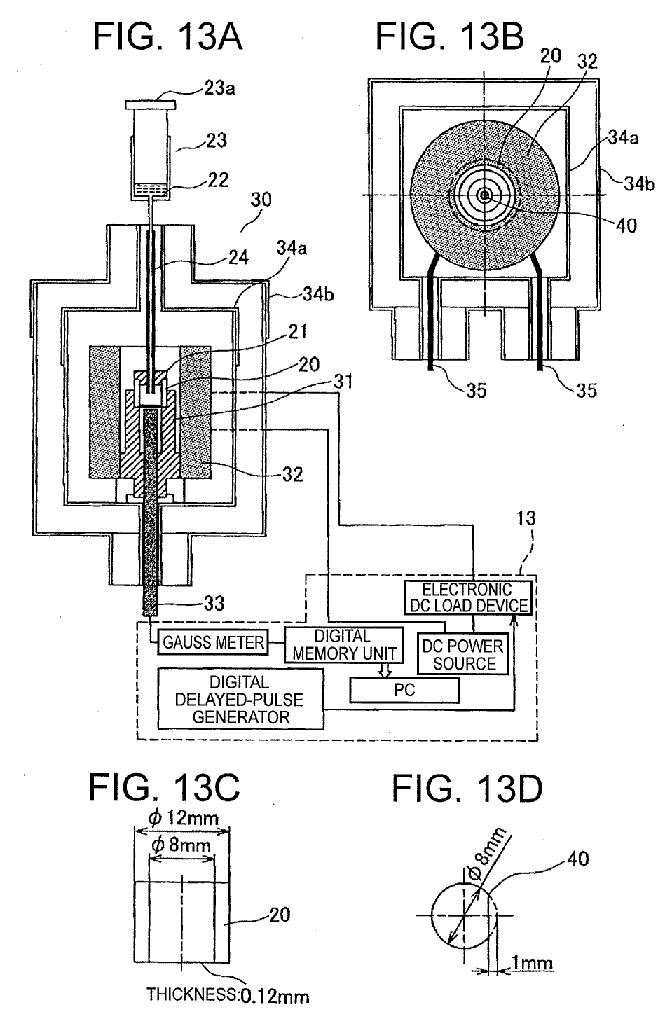

The experiment was carried out using a Meissner effect verification apparatus 30 illustrated in FIG. 13. FIG. 13C illustrates a glass container 20 disposed at a centre of the apparatus. The thickness of the bottom portion of the glass container 20 is 0.12 mm.

The glass container 20 is, as illustrated in the schematic lateral cross-sectional view of FIG. 13A, placed upon a placement jig 31 made of PTFE at the central portion of the Meissner effect verification apparatus 30 with its upper portion covered by a lid 21 made of PTFE. The lid 21 includes a throughhole, and a tube 24 made of PTFE passing through the throughhole is connected to a syringe 23 residing above the glass container 20, and a proton donor 22 (in a liquid state) contained in the syringe 23 is operable to be introduced into the glass container 20 by operation of a plunger 23a.

Meanwhile, a throughhole is provided at the centre of the placement jig 31, and a hall probe 33 is inserted into the throughhole from below, so that the magnetic field can be detected that is near the bottom portion of the glass container 20.

A coil 32 is arranged around the glass container 20 for generation of the magnetic field.

Further, permalloy magnetic shield containers 34a and 34b are arranged around the coil 32 in a two-fold manner so as to ensure highly-accurate measurement while external magnetism such as geomagnetism is shut out. Also, as shown in FIG. 13B illustrating a schematic top cross-sectional view, an introduction passage is provided for the lead of the coil 32.

The coil 32 and the hall probe 33 are connected to each other via the magnetization and measurement unit 13 used in FIG. 8.

As the substance composed of graphenes, graphite (HOPG) with a weight of 0.0048 g and a thickness (calculated value) of 0.004 mm when the specific gravity is 2.2 is used, whose shape is illustrated in FIG. 13D. The graphite (HOPG) was put on the bottom portion in the glass container 20.

With regard to the shape of the graphite, there is provided a notch so that the later-described n-octane reaches the backside.

The experiment was carried out as follows.

The graphite was put in the glass container 20, and the glass container 20 was connected to the Meissner effect verification apparatus 30 illustrated in FIG. 13A. The magnetic filed was produced by the coil 32 within the glass container 20. After that (three minutes later), the plunger 23a of the syringe 23 was operated to apply the n-octane (0.1 mL) in the syringe 23 in drops to the glass container 20.

Here, the distance from a bottom portion of the sample within the glass container to a sensor of the hall probe 33 is 2 mm.

Change in the magnetic field in that state was detected.

The magnetic field applied to the graphite were 180 G, 150 G, 100 G, 50 G, 10 G, 1 G, 0.1 G, or very small magnetic field (and yet at least larger than zero G, which is due to slight geomagnetism detected by the hall probe 33 within magnetic shield containers 34a and 34b). The very small magnetic field may be hereafter indicated as ˜0 G (>0).

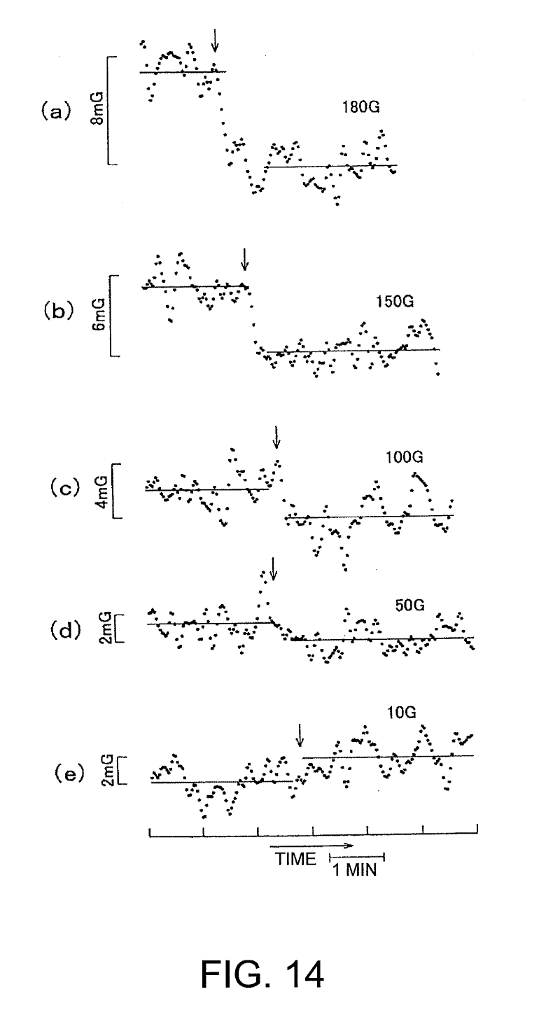

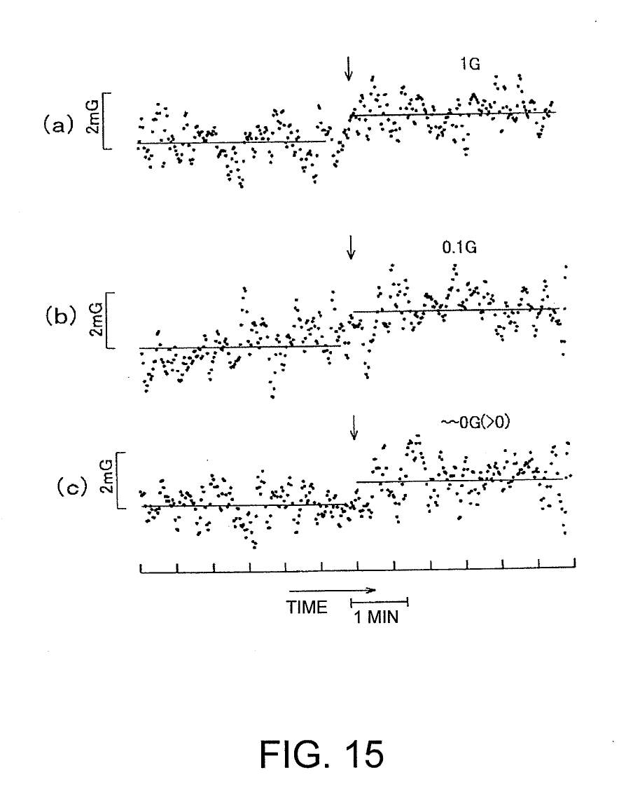

The portions (a), (b), (c), (d), and (e) in FIG. 14 depict the results in the cases of the applied magnetic fields of 180 G, 150 G, 100 G, 50 G, and 10 G, respectively. The portions (a), (b), and (c) in FIG. 15 depict the results in the cases of the applied magnetic fields of 1 G, 0.1 G, and ˜0 G (>0), respectively. The arrows in these figures represent the timing of the starting of the application in drops of the n-octane.

It is confirmed from these figures that, under the magnetic field of 180 G, diamagnetism of 8 mG appears, and in the magnetic field equal to or less than that, decrease in the magnetic field is observed substantially in proportion to the strengths of the magnetic field, and the Meissner effect was confirmed that is characteristic of superconductive substances.

However, in the case of less than 50 G, diamagnetism was not observed, but ferromagnetism occurs. Specifically, since it is appreciated that ferromagnetism is observed when the hydrocarbon is brought into contact with the substance composed of graphenes, magnetization occurs even when the magnetic field is almost zero G, i.e., ˜0 G (>0), which indicates that spontaneous magnetization arises by the combination of the graphite surface and the hydrocarbon, and by virtue of this combination, a ferromagnetic body is formed.

Further, examination was carried out to confirm if the superconductor to which a magnetic field of 10 G or larger were applied (where the Meissner effect was confirmed) also exhibits ferromagnetism.

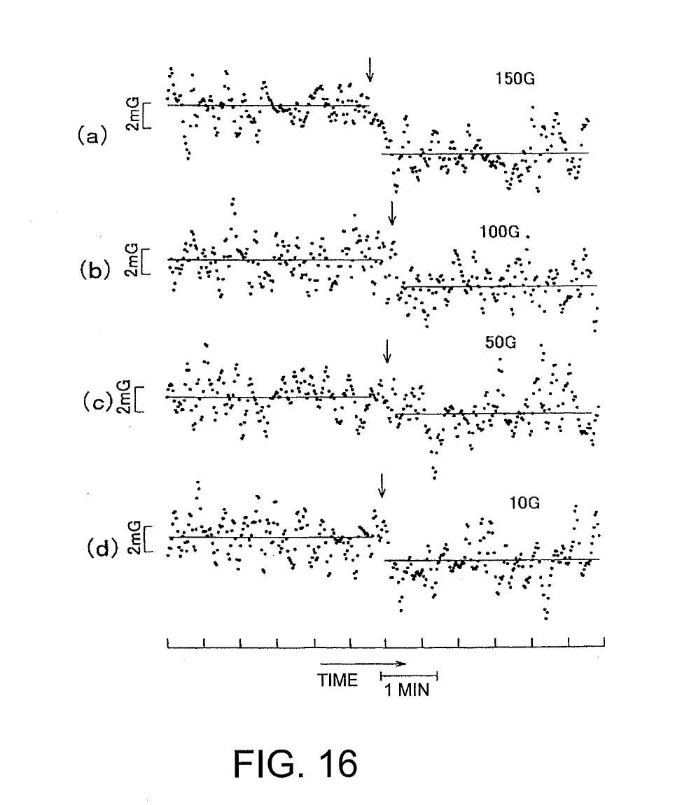

While magnetic fields of 150 G, 100 G, 50 G, and 10 G were applied to the graphite samples (HOPG plate) accommodated in the glass container, the n-octane was dropped to the graphite samples. After that, the application of the magnetic field was stopped and then the glass container containing therein the graphite and the n-octane was removed from the Meissner effect verification apparatus. The portions (a), (b), (c), and (d) in FIG. 16 depict the changes in the magnetic field measured by the hall probe at the time of removal of the glass container (the arrows in the figure represent the timing of the removal of the glass container).

From these results, it can be appreciated that the mixture of the n-octane and the graphite was magnetized.

Although the octane exhibits the diamagnetism, its diamagnetic susceptibility is extremely small (−96.6 3×10⁻⁶ cm³ mol⁻¹) and it has almost no effect upon the magnetic field at the position of the hall sensor spaced by the glass container (whose bottom thickness is 0.12 mm).

If it is assumed that the observed diamagnetism originates from the mixture of the n-octane and the graphite plate, then the diamagnetic susceptibility of the mixture of the n-octane and the graphite is several orders of magnitude larger than the diamagnetic susceptibility of the octane.

Thus, although the perfect diamagnetism is not observed, the complex comprising the substance composed of graphenes and the proton donor not only is the perfect conductor but also is classified as the superconductor.

1. A room-temperature superconductor comprising:
(a) a substance composed of graphene; and
(b) a proton donor.

2. The room-temperature superconductor of claim 1, wherein said substance composed of graphene is at least one selected from the group consisting of carbon nanotube, fullerene, and graphite.

3. The room-temperature superconductor of claim 2, wherein said graphite is carbon fiber.

4. The room-temperature superconductor of any one of claims 1 to 3, wherein said proton donor is hydrocarbon.

5. The room-temperature superconductor of claim 4, wherein said hydrocarbon is straight-chain hydrocarbon.

6. A method for producing a room-temperature superconductor, comprising bringing a proton donor into contact with a substance composed of graphene.

7. A perfect conductor comprising:
(a) a substance composed of graphene; and
(b) a proton donor.

8. A method for producing a perfect conductor, comprising bringing a proton donor into contact with a substance composed of graphene.

9. A protonic conductor comprising:
(a) a substance composed of graphene; and
(b) a proton donor.

10. A method for producing a protonic conductor, comprising bringing a proton donor into contact with a substance composed of graphene.

11. A ferromagnetic body comprising:
(a) a substance composed of graphene; and
(b) a proton donor.

12. A method for producing a ferromagnetic body, comprising bringing a proton donor into contact with a substance composed of graphene.

13. An electromagnetic coil comprising a material selected from the group consisting of (a) the room-temperature superconductor of any one of claims 1 to 3 and (b) the perfect conductor including:
(a) a substance composed of graphene; and
(b) a proton donor.
